(19) United States
(12) Patent Application Publication
(10) Pub. No.: US 2023/0230930 A1
(43) Pub. Date: Jul. 20, 2023

(54) SEMICONDUCTOR STRUCTURE WITH BACKSIDE THROUGH SILICON VIAS AND METHOD OF OBTAINING DIE IDS THEREOF

(71) Applicant: UNITED MICROELECTRONICS CORP., Hsin-Chu City (TW)

(72) Inventor: Kuang-Hui Tang, Kaohsiung City (TW)

(73) Assignee: UNITED MICROELECTRONICS CORP., Hsin-Chu City (TW)

(21) Appl. No.: 17/674,796

(22) Filed: Feb. 17, 2022

(30) Foreign Application Priority Data
Jan. 18, 2022 (TW) 111102004

(51) Int. Cl. H01L 23/544; H01L 23/48; H01L 23/528; H01L 29/20; H01L 29/40; H01L 29/45; H01L 29/47; H01L 29/778; H01L 21/768; H01L 21/66

(52) U.S. Cl. CPC H01L 23/544; H01L 23/481; H01L 23/5286; H01L 29/2003; H01L 29/402; H01L 29/452; H01L 29/475; H01L 29/7786; H01L 21/76898; H01L 22/12; H01L 2223/5444

(57) ABSTRACT

A semiconductor structure with backside through silicon vias (TSVs) is provided in the present invention, including a semiconductor substrate with a front side and a back side, multiple dummy pads set on the front side, multiple backside TSVs extending from the back side to the front side, wherein a number of the dummy pads are connected with the backside TSVs while other dummy pads are not connected with the backside TSVs, and a metal coating covering the back side and the surface of backside TSVs and connected with those dummy pads that connecting with the backside TSVs.

### BACKGROUND OF THE INVENTION

### 1. Field of the Invention

The present invention relates to a semiconductor structure, and more specifically, to a semiconductor structure with backside through silicon vias (TSVs) and method of obtaining die IDs thereof.

### 2. Description of the Prior Art

Generally speaking, die IDs are used in semiconductor field to provide information of every die on a wafer, including the information of manufacturer, date of production, production line, the X/Y numerical coordinates and position of the die on the wafer, etc. This information may be used in yield improvement analysis to analyze the problem in order to improve die yield. However, current GaN RF (radio frequency) wafer or shuttle wafer are not provided with any die IDs design. Therefore, the approach now available in the industry is to request package foundry to handwrite die IDs that can provide position information or other information of every die. This approach not only affects the production cycle of product, but also error-prone in actual execution, and package foundry may also refuse to provide this service. Accordingly, it is necessary for those of skilled in the art in the industry to research and develop other method that can easily generate and obtaining die IDs for dies or semiconductor wafers after package.

### SUMMARY OF THE INVENTION

In the light of current GaN RF wafer or shuttle wafer not provided with any die IDs design, the present invention hereby provides a novel semiconductor structure, featuring the design of setting dummy pads that may connect with backside through silicon vias (TSVs) or not to define the logic states of those dummy pads, which may be provided to final test module after package for reading product's data designated therein.

One aspect of the present invention is to provide a semiconductor with backside through silicon vias (TSVs), including components of a semiconductor substrate with a front side and a back side, multiple dummy pads on the front side, multiple backside TSVs extending from the back side to the front side, wherein a number of the dummy pads connect with the backside TSVs, and the other dummy pads do not connect with the backside TSVs, and a metal coating covering the back side and surfaces of the backside TSVs and connecting with the number of dummy pads that connect with the backside TSVs.

Another aspect of the present invention is to provide a method of obtaining die IDs, including steps of providing a semiconductor substrate having multiple dies, wherein each die has a front side and a back side, forming multiple dummy pads on the front side, forming multiple backside TSVs extending to the front side from the back side, wherein a number of the dummy pads connect with the backside TSVs, and the other dummy pads do not connect with the backside TSVs, forming a metal coating on the back side and on surfaces of the backside TSVs, wherein the metal coating connects with the number of dummy pads that connect with the backside TSVs, and grounding the metal coating and defining said number of dummy pads that are grounded through said metal coating as being in “1” logic state and the other dummy pads that aren't grounded through the metal coating as being in “0” logic state.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic cross-section of a semiconductor structure in accordance with a preferred embodiment of the present invention;

FIG. 2 is a partially enlarged cross-section of the semiconductor structure in accordance with the preferred embodiment of the present invention; and

FIG. 3 is a schematic plan view illustrating the semiconductor structure of present invention connecting with a package structure.

Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

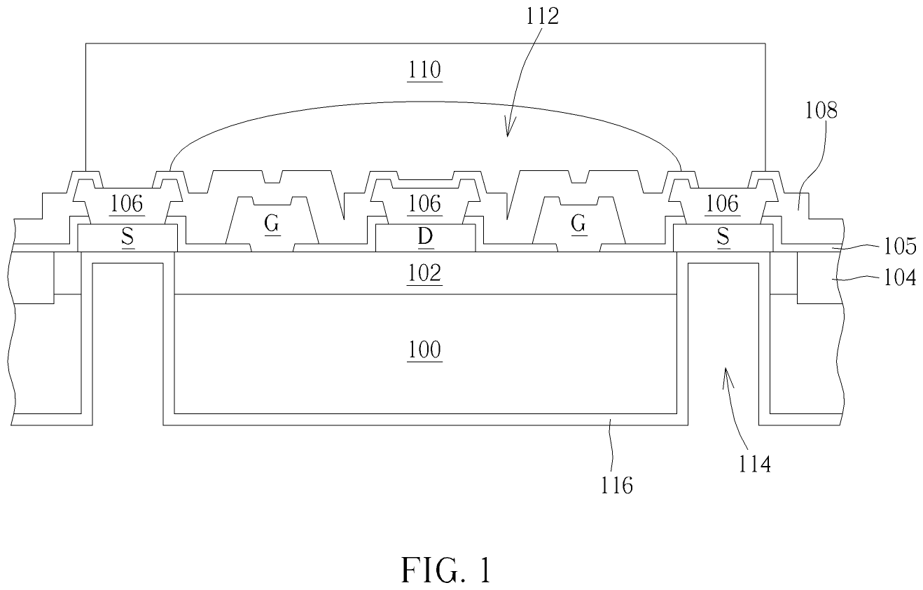

First, please refer to FIG. 1, which is a schematic cross-section of a semiconductor structure in accordance with one preferred embodiment of the present invention. A GaN-on-Si (gallium nitride on silicon) substrate is shown as an example in FIG. 1 to describe components and relevant arrangement of the semiconductor structure in present invention. This kind of GaN-based substrate is provided with extremely high electron saturation velocity, band gap, breakdown field, thermal conductivity and operating temperature, which is particularly suitable for being used in the manufacture of high-power devices or radio-frequency (RF) device, such as 5G communication devices or automotive voltage devices. Nevertheless, please note that the semiconductor structure of present invention and relevant method of obtaining die IDs thereof are not limited in the GaN-on-Si substrate described in the embodiment. Instead, they can be used in any kinds of semiconductor structures, for example, conventional silicon substrate, SiGe substrate or GaN-on-SiC (gallium nitride on silicon carbide) substrate.

As shown in FIG. 1, a semiconductor substrate is first provided. The semiconductor substrate may be a GaN-on-Si substrate, including a silicon substrate 100, ex. a silicon substrate with crystallographic direction <111>, and a GaN layer 102 on the silicon substrate 100. Multiple alternating GaN/AlGaN buffer layer or superlattic structure may be provided between silicon substrate 100 and GaN layer 102, and a barrier layer (not shown) may be further provided on GaN layer 102. A MESA process may be first performed to the semiconductor substrate to form isolation structure, such as a silicon nitride layer 104, to define individual active areas. Components like gates G, drain D and source S are formed on the surface of GaN layer 102. Two-dimensional electron gas (2DEG) or two-dimensional hole gas (2DHG) formed at the heterojunction in the substrate and these components may collectively constitute high electron mobility transistor (HEMT) or high hole mobility transistor (HHMT). Gate G may be a T-shaped gate, with a bottom connecting to underlying GaN layer 102. The material of gate G may be Au or Ni/Au alloy, which may be formed by deposition and lift-off process. A liner 105, such as an aluminum nitride (AlN) layer, may be further provided between other parts of gate G and GaN layer 102. Source S and drain D may be ohmic contact metal, which are formed directly on the surface of GaN layer 102 with a material like the one of gate G, ex. Ni/Au alloy or Ti/Al/Ni/Au alloy. The liner 105 covers on parts of surfaces of the sources S and drains D.

Refer still to FIG. 1. In the embodiment, through silicon vias (TSVs) 114 are formed under sources S and drains D, which pass through entire silicon substrate 100 and GaN layer to connect with source S. TSVs 114 may be formed by laser ablation process or dry etching process, with a diameter preferably smaller than the width of source S. A backside metal coating 116, such as a plating gold, may be formed on the back side of semiconductor substrate and on surfaces of backside TSVs 114 through electroplating process. The metal coating 116 may be patterned into circuit patterns in seed layer stage. In the embodiment, backside metal coating 116 is electrically connected with source S and drain D through TSVs 114, so that GaN devices may be grounded through metal coating 116 to improve their high-frequency parasitic inductance effect. In addition to backside TSVs 114, bonding pads 106 may be further formed on sources S and drains D with a material like Ti/Au through the same process as the one of gate G. A passivation layer 108 may be further formed on the surface of entire substrate. The material of passivation layer 108 may be silicon nitride (SiNₓ), which may be covered on surfaces of gates G, drains D and sources S through PECVD process to provide protection. Moreover, in order to further improve the breakdown field of GaN devices and to promote their stability in elevated operating temperature, an air bridge field plate (AFP) 110 is formed above the devices. Two ends of the air bridge field plate 110 are connected respectively to two bonding pads 106 on sources S, with its concave part partially overlapping the components like gates G and drains D below and forming an air gap 112 therebetween. The material of air bridge field plate 110 may be the same as the one of bonding pads 106, such as Au, Ti/Au alloy or Ti/Al/Ni/Au alloy, which may be formed through conventional field plate process.

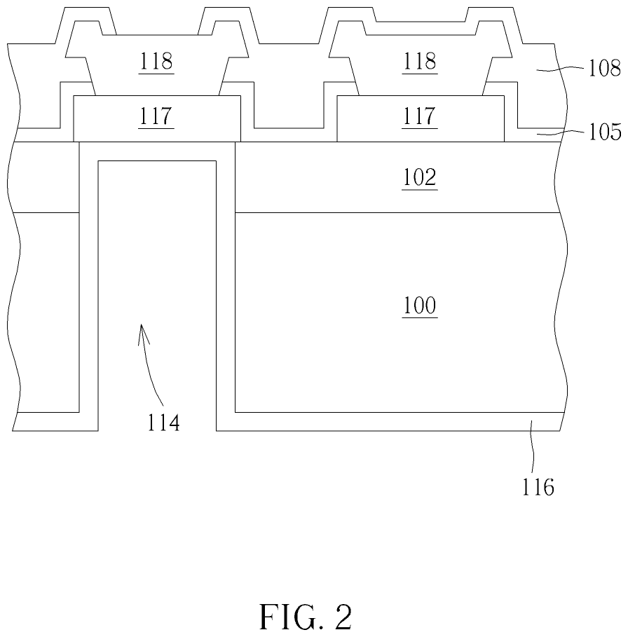

Please refer now to FIG. 2, which is a partially enlarged cross-section of the semiconductor structure in accordance with the preferred embodiment of the present invention. In addition to the aforementioned various components of GaN device, the key point of present invention is to achieve the effect of generating and obtaining required die IDs for the semiconductor substrate through the setting of dummy pads. As shown in FIG. 2, multiple dummy pads 118 are further formed on the semiconductor substrate, with an ohmic contact metal layer 117 formed between dummy pads 118 and GaN layer 102. The material and process of dummy pads 118 may be the same as the ones of aforementioned bonding pads 106, such as Ti/Au alloy formed through deposition and lift-off processes. The material of ohmic contact metal layer 117 may be the same as the one of aforementioned sources S, such as Ni/Au alloy or Ti/Al/Ni/Au alloy. Similarly, liner 105 and passivation layer 108 are also covered on surfaces of dummy pads 118 and ohmic contact metal layer 117 to provide protection.

Refer still to FIG. 2. Please note that in the embodiment of present invention, unlike sources S, air bridge field plate 110 doesn't connect to dummy pads 118, and a number of dummy pads 118 are designedly connected with backside TSVs 114 below while the other dummy pads 118 are designedly not connected with backside TSVs 114. Similarly, the dummy pads 118 connecting with the backside TSVs 114 are grounded through the backside metal coating 116. In the present invention, since the setting of aforementioned dummy pads 118, the dummy pads 118 grounded through the metal coating 116 may be defined as being in “1” logic state and the other dummy pads 118 that aren't grounded may be defined as being in “0” logic state. In this way, through the approach of setting multiple dummy pads 118 with different properties and binary logic states on the semiconductor substrate, the effect of generating die IDs for the semiconductor substrate may be achieved.

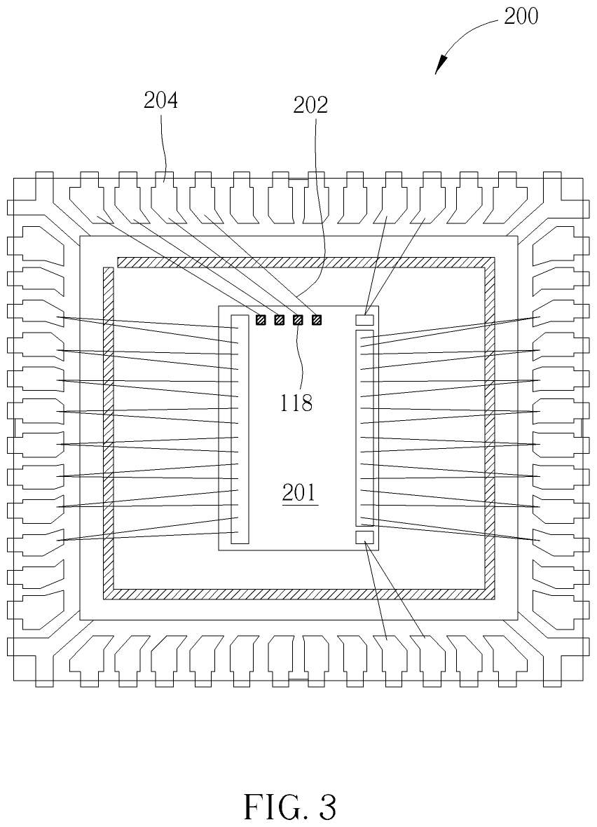

Please refer now to FIG. 3, which is a schematic plan view illustrating the semiconductor structure of present invention connecting with a package structure. A quad flat no-lead (QFN) package structure is shown in FIG. 3 as an example to describe the method of obtaining die IDs of the present invention. Please note that the semiconductor structure of present invention and relevant method of obtaining die IDs thereof are not limited in the QFN package described in the embodiment. Instead, they may be used in any kinds of package structures, for example conventional ball grid array (BGA) package or surface-mount technology (SMT) package.

As shown in FIG. 3, after the manufacture of aforementioned semiconductor devices is completed, the semiconductor substrate may be diced into individual dies 20 through a dicing process. These dies 201 will be encapsulated and fixed in a package structure 200 through a package process, and they will also be electrically connected to pins 204 of the package structure 200 through bonding wires 202 or lead frame in order to be further connected with external circuit board or device. In the embodiment of present invention, each die 201 is provided with corresponding dummy pads 118, wherein ID information of the die is provided through these dummy pads 118 in a form of binary logic state, i.e. implemented through determining if these dummy pads 18 are connected with backside grounded metal coating or not. Through the dummy pads 118 that are electrically connected to pins 204 of the package structure 200 by bonding wires 202, a final electrical test may be performed after package to obtain the electrical properties of those dummy pads 118, i.e. their current binary logic states, so as to obtain the ID information of the die 201. This ID information may include the information like manufacturer, date of production, production line, the X/Y numerical coordinates and position of the die on the wafer, etc. The information may be used in following yield improvement analysis to analyze the problem and improve die yield.

In summary of aforementioned embodiments, it can be understood that the semiconductor structure of present invention adopts the approach of forming dummy pads and connecting backside TSVs to generate IDs and obtain required product information designated therein for semiconductor substrates or dies, thereby solving the problem of current GaN RF wafer or shuttle wafer not provided with any die IDs design and the problem of die IDs unable to be obtained after package in prior art, which is an invention provided both with novelty and non-obviousness.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor with backside through silicon vias (TSVs), comprising:
a semiconductor substrate with a front side and a back side;
multiple dummy pads on said front side;
multiple backside TSVs extending from said back side to said front side, wherein a number of said dummy pads connect with said backside TSVs, and the other said dummy pads do not connect with said backside TSVs; and
a metal coating covering said back side and surfaces of said backside TSVs and connecting with said number of dummy pads that connect with said backside TSVs.

2. The semiconductor with backside TSVs of claim 1, further comprising multiple transistors on said semiconductor substrate, wherein a source of said transistor connects with one said backside TSV.

3. The semiconductor with backside TSVs of claim 2, wherein said transistor is high electron mobility transistor.

4. The semiconductor with backside TSVs of claim 2, wherein said source and a drain of said transistors are ohmic contact metal made of Ni/Au alloy or Ti/Al/Ni/Au alloy.

5. The semiconductor with backside TSVs of claim 4, further comprising a liner covering on parts of surfaces of said source and said drain, and a material of said liner is aluminum nitride.

6. The semiconductor with backside TSVs of claim 4, further comprising bonding pads formed on said sources and said drains, and a material of said bonding pad and said dummy pad is Ti/Au alloy.

7. The semiconductor with backside TSVs of claim 4, further comprising an air bridge field plate formed above said transistors, wherein two ends of said air bridge field plate connect respectively to two of said sources.

8. The semiconductor with backside TSVs of claim 2, wherein a gate of said transistor is T-shaped gate made of Au or Ni/Au alloy.

9. The semiconductor with backside TSVs of claim 2, further comprising a passivation layer covering on said transistors, and a material of said passivation layer is silicon nitride.

10. The semiconductor with backside TSVs of claim 1, wherein said semiconductor substrate is a GaN-on-Si substrate.

11. The semiconductor with backside TSVs of claim 1, wherein said metal coating is plating gold.

12. The semiconductor with backside TSVs of claim 1, further comprising an ohmic contact metal layer formed between said dummy pads and said semiconductor substrate, wherein a material of said ohmic contact metal layer is Ni/Au alloy or Ti/Al/Ni/Au alloy.

13. A method of obtaining die IDs, comprising:
providing a semiconductor substrate having multiple dies, wherein each said die has a front side and a back side;
forming multiple dummy pads on said front side;
forming multiple backside TSVs extending to said front side from said back side, wherein a number of said dummy pads connect with said backside TSVs, and the other said dummy pads do not connect with said backside TSVs;
forming a metal coating on said back side and on surfaces of said backside TSVs, wherein said metal coating connects with said number of dummy pads that connect with said backside TSVs; and
grounding said metal coating and defining said number of dummy pads that are grounded through said metal coating as being in “1” logic state and said the other dummy pads that aren't grounded through said metal coating as being in “0” logic state.

14. The method of obtaining die IDs of claim 13, further comprising wire-bonding said dummy pads to pins of a package structure and performing an electrical test to obtain a ID of said die through determining if said dummy pads are grounded or not.

15. The method of obtaining die IDs of claim 14, wherein said package structure is quad flat no leads package structure.

16. The method of obtaining die IDs of claim 14, wherein said ID designates a position of said die on said semiconductor substrate.

17. The method of obtaining die IDs of claim 13, wherein said backside TSVs are formed by laser ablation process or dry etching process.

18. The method of obtaining die IDs of claim 13, further comprising multiple transistors on said semiconductor substrate, and each said transistor is provided with a source, a drain and a gate, wherein said source of said transistor is connected with one said backside TSV.

19. The method of obtaining die IDs of claim 18, further comprising bonding pads formed on said sources and said drains, and a material of said bonding pad and said dummy pad is Ti/Au alloy.

20. The method of obtaining die IDs of claim 13, further comprising an ohmic contact metal layer formed between said dummy pads and said semiconductor substrate, and said ohmic contact metal layer is made of Ni/Au alloy or Ti/Al/Ni/Au alloy.
